(19) United States
(12) Patent Application Publication
(10) Pub. No.: US 2025/0053081 A1
(43) Pub. Date: Feb. 13, 2025

(54) IMPRINT LITHOGRAPHY DEFECT MITIGATION METHOD AND MASKED IMPRINT LITHOGRAPHY MOLD

(71) Applicant: LEIA Inc., Menlo Park, CA (US)

(72) Inventors: Kevin Cao, Menlo Park, CA (US); Sonny Vo, Menlo Park, CA (US); Qing Yang, Menlo Park, CA (US); Felix Mbuga, Menlo Park, CA (US)

(21) Appl. No.: 18/720,487

(22) PCT Filed: Dec. 20, 2021
(86) PCT No.: PCT/US2021/064320

§ 371 Date: Jun. 14, 2024

(51) Int. Cl. G03F 7/00; G03F 7/16

(52) U.S. Cl. CPC G03F 7/0002; G03F 7/162

(57) ABSTRACT

A method of imprint lithography mold defect mitigation and a masked imprint lithography mold employ a masking layer to selectively cover a surface defect. The method of imprint lithography mold defect mitigation includes depositing a masking layer on a surface of an imprint lithography mold to selectively cover a defect on the surface and form a masked imprint lithography mold. The method of imprint lithography mold defect mitigation further includes forming a negative imprint lithography mold from the masked imprint lithography mold. The masked imprint lithography mold includes an imprint lithography mold having a surface with a defect and a patterned masking layer affixed to the surface and configured to selectively cover the defect. The patterned masking layer that selectively covers the defect is configured to mitigate an effect of the defect when the masked imprint lithography mold is employed in imprint lithography.

### CROSS-REFERENCE TO RELATED APPLICATIONS

N/A

### STATEMENT REGARDING FEDERALLY SPONSORED RESEARCH OR DEVELOPMENT

N/A

### BACKGROUND

Electronic displays are a nearly ubiquitous medium for communicating information to users of a wide variety of devices and products. Among the most commonly found electronic displays are the cathode ray tube (CRT), plasma display panels (PDP), liquid crystal displays (LCD), electroluminescent displays (EL), organic light emitting diode (OLED) and active matrix OLEDs (AMOLED) displays, electrophoretic displays (EP) and various displays that employ electromechanical or electrofluidic light modulation (e.g., digital micromirror devices, electrowetting displays, etc.). Many of these modern displays require high precision manufacturing to fabricate various display structures and elements.

Imprint lithography, including imprint lithography, is among a number of fabrication techniques for producing various structures and elements associated with modern electronic displays. In particular, imprint lithography generally excels at providing sub-micrometer or nanoscale features having very high precision and is readily adaptable to mass production. For example, imprint lithography may be used to create a stamp or mold having nano-scale features by aggregating together or tiling wafers having nanoscale imprint patterns. The mold master may be used in imprint lithography to imprint patterns onto a receiving substrate. Further, various high-volume fabrication methodologies, including but not limited to roll-to-roll imprinting, may be used in conjunction with imprint lithography and a mold master for mass production. However, providing sub-micrometer or nanoscale feature precision over a large-area mold master may be problematic. In particular, maintaining nanoscale precision across the large-area mold master may be hampered, in practice, if nanoscale features extend beyond a boundary of a single wafer or device.

### BRIEF DESCRIPTION OF THE DRAWINGS

Various features of examples and embodiments in accordance with the principles described herein may be more readily understood with reference to the following detailed description taken in conjunction with the accompanying drawings, where like reference numerals designate like structural elements, and in which:

FIG. 1 illustrates a flow chart of a method of imprint lithography mold defect mitigation in an example, according to an embodiment of the principles described herein.

FIG. 2 illustrates a flow chart of a method of surface defect mitigation in imprint lithography in an example, according to another embodiment of the principles described herein.

FIG. 3 illustrates a cross-sectional view of a masked imprint lithography mold 300 in an example, according to an embodiment consistent with the principles described herein.

FIG. 4A illustrates a cross-sectional view of imprint lithography mold in an example, according to an embodiment consistent with the principles described herein.

FIG. 4B illustrates a cross-sectional view of the imprint lithography mold of FIG. 4A in an example, according to an embodiment of the principles described herein.

FIG. 4C illustrates a cross-sectional view of a negative imprint lithography mold in an example, according to an embodiment consistent with the principles described herein.

FIG. 4D illustrates a cross-sectional view of a positive imprint lithography mold in an example, according to an embodiment consistent with the principles described herein.

FIGS. 5A-5C illustrate a cross-sectional view of imprint lithography mold having a defect in an example, according to an embodiment consistent with the principles described herein.

Certain examples and embodiments have other features that are one of in addition to and in lieu of the features illustrated in the above-referenced figures. These and other features are detailed below with reference to the above-referenced figures.

### DETAILED DESCRIPTION

Examples and embodiments in accordance with the principles described herein may mitigate an effect of defects on an imprint lithography mold used for imprint lithography. In particular, according to various embodiments of the principles described herein, a masking layer deposited on a surface of an imprint lithography mold may be used to selectively cover a surface defect on the imprint lithography mold surface. Selectively covering the surface defect, in turn, may enable imprint lithography using a masked imprint lithography mold with a selectively covered surface defect to provide high quality, essentially defect-free results. Surface defects may be of particular importance when using imprint lithography to produce optical devices such as, but not limited to, diffractive backlights that include light guides and nanoscale diffractive scattering features used in various electronic displays, e.g., multiview displays. Moreover, imprint lithography mold defect mitigation may be useful in providing high quality imprint lithography molds that are larger than available imprint lithography master substrates, according to some embodiments.

In particular, a defect may be created during tiling imprint lithography master substrates. For example, imprint lithography master substrates are often tiled to form an imprint lithography mold that is larger than the individual imprint lithography master substrates. Tiling, comprising arranging and abutting the individual imprint lithography master substrates together with one another, may create defects often referred to as a ‘stitch line’ at a boundary between the abutted imprint lithography master substrates. Especially in optical applications, the presence of a stitch line or similar defect if transferred to a product produced using the imprint lithography mold can often render the product unacceptable for its intended purpose. In addition to stitch line defects, various other material and process issues may also lead to the surface defects on the imprint lithography mold. As such, mitigation of defects and in particular surface defects may significantly improve yield as well as decrease costs associated with attempts to avoid the creation of surface defects.

Herein, ‘imprint lithography’ is defined as either ‘micro-imprint lithography’ or ‘nanoimprint lithography,’ according to various specific embodiment. In particular, ‘micro-imprint lithography’ is defined as imprint lithography involving the fabrication of devices or molds having micrometer scale dimensions or micrometer size features, while ‘nanoimprint lithography’ is defined as imprint lithography involving sub-micrometer or nanoscale dimensions and features. For example, nanoimprint lithography may be used in conjunction with fabrication of an imprint lithography mold having sub-micrometer (nanoscale) size features and its precise replication as an imprint stamp to enable high precision and low cost manufacturing of such structures (e.g., for displays and solar panels) may be provided. Such imprint lithography molds may be used to produce a large-scale display or other typically two-dimensional (2D) structure that requires, or at least benefits from, sub-micrometer or nanoscale precision over a large-area substrate. Combining high precision sub-micrometer patterning and large-scale manufacturing may considerably lower the technical and cost barrier for new applications such as displays including, but not limited to, diffractive light field displays, plasmonic sensors, and various metamaterials for clean energy, biological sensors, memory or storage disks, etc., to name a few.

As used herein, ‘micrometer scale’ refers to dimensions within a range of one micrometer (1 μm) to one thousand micrometers (1000 μm). Further as used herein, ‘sub-micrometer scale’ refers to dimensions less than 1 μm. As used herein, ‘nanometer scale’ or ‘nanoscale’ may be used interchangeably and refer to dimensions within a range of one nanometer (1 nm) to less than one thousand nanometers (1000 nm), i.e., less than one micrometer (<1 μm). As such, ‘sub-micrometer’ and ‘nanometer’ and their equivalents may also be used interchangeably. Further herein, “large-area” is defined as a structure that is generally more than two orders of magnitude larger than size of a sub-micrometer or nanoscale structure of an imprint lithography mold. For example, a large-area substrate may have a size that is on the order of meters-by-meters or feet-by-feet, while the nanoscale features are on the order of nanometers to micrometers in size, in some embodiments.

By definition herein, an ‘imprint lithography master substrate’, also often referred to as a ‘wafer’ or a ‘sub-master tile’ having nanoscale features may have a maximum size that is less than about thirty centimeters (30 cm), e.g., less than 30 cm×30 cm. In particular, a size of an imprint lithography master substrate may be limited by a size of available substrates (e.g., semiconductor wafers) upon which or from which the imprint lithography master substrate is fabricated. For example, production silicon wafers often used in the fabrication of imprint lithography master substrates (e.g., using electron-beam lithography or a similar technique) are currently limited to a maximum size of about 30 cm. On the other hand, an imprint lithography mold may be greater than about one meter (m), e.g., greater than 1 m×1 m. That is, a size of the imprint lithography may be dictated by a size of a final product (e.g., a size of a backlight of an electronic display) that is to be produced by imprint lithography using the imprint lithography mold. The larger size of the imprint lithography mold when compared to the imprint lithography master substrate may be provided by tiling of the imprint lithography master substrates, according to various embodiments.

Further, as used herein, the article ‘a’ is intended to have its ordinary meaning in the patent arts, namely ‘one or more’. For example, ‘a defect’ means one or more defects and as such, ‘the defect’ means ‘the defect(s)’ herein. Also, any reference herein to ‘top’, ‘bottom’, ‘upper’, ‘lower’, ‘up’, ‘down’, ‘front’, back', ‘first’, ‘second’, ‘left’ or ‘right’ is not intended to be a limitation herein. Herein, the term ‘about’ when applied to a value generally means within the tolerance range of the equipment used to produce the value, or may mean plus or minus 10%, or plus or minus 5%, or plus or minus 1%, unless otherwise expressly specified. Further, the term ‘substantially’, as used herein, means a majority, or almost all, or all, or an amount within a range of about 51% to about 100%. Moreover, examples herein are intended to be illustrative only and are presented for discussion purposes and not by way of limitation.

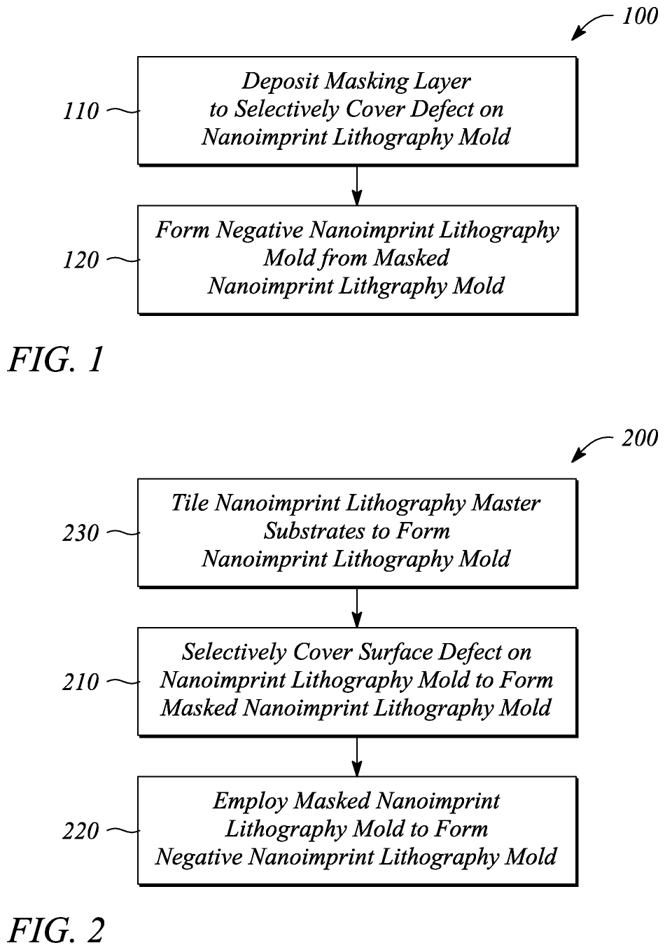

According to some embodiments of the principles described herein, a method of imprint lithography mold defect mitigation is provided. FIG. 1 illustrates a flow chart of a method 100 of imprint lithography mold defect mitigation in an example, according to an embodiment of the principles described herein. As illustrated the method 100 of imprint lithography mold defect mitigation comprises depositing 110 a masking layer on a surface of an imprint lithography mold. In particular, depositing 110 the mask layer is configured to selectively cover a defect on the surface and form a masked imprint lithography mold.

In some embodiments, depositing 110 the masking layer to selectively cover a defect may comprise applying a photoresist to the surface of the imprint lithography mold having the defect. Applying the photoresist may comprise coating the photoresist on the surface of the imprint lithography mold, in some embodiments. Any of a variety of different coating techniques may be employed to coat the photoresist on the surface including, but not limited to, spin coating, slit coating, and spray coating. According to various embodiments, depositing 110 the masking layer further comprises patterning the photoresist using a photolithographic mask to expose the photoresist. Following using the photolithographic mask to pattern and expose the photoresist, depositing 110 the masking layer further comprises developing the exposed photoresist to pattern the masking layer on the surface of the imprint lithography mold to form the masked imprint lithography mold. For example, the exposed photoresist may be developed by immersion in a chemical developer solution to remove portions of the photoresist.

In other embodiments, depositing 110 the patterned masking layer to selectively cover a defect comprises providing the patterned masking layer as a patterned preform film followed by aligning the patterned masking layer with the imprint lithography mold having the defect. According to these embodiments, depositing 110 the patterned masking layer further comprises applying the patterned preform film to the surface of the imprint lithography mold to form masked imprint lithography mold. The patterned preform film may be aligned to the surface of the imprint lithography prior to being applied using one or more alignment marks on the imprint lithography mold, for example.

As illustrated in FIG. 1, the method 100 of imprint lithography mold defect mitigation further comprises forming 120 a negative imprint lithography mold from the masked imprint lithography mold. In some embodiments, forming 120 the negative imprint lithography mold may comprise pressing the masked imprint lithography mold into a receiving layer on a substrate using imprint lithography. The substrate and receiving layer become the formed negative imprint lithography mold after pressing, accordingly.

In some embodiments (e.g., as illustrated in FIG. 1), the method 100 of imprint lithography mold defect mitigation may further comprise forming 130 a patterned device substrate using imprint lithography employing the negative imprint lithography mold. In particular, the negative imprint lithography mold may be used to imprint a receiving layer of the patterned device substrate. In some embodiments, the receiving layer comprises an ultraviolet-curable (UV-curable) hybrid polymer, especially one with good optical qualities. Examples of a UV-curable hybrid polymers having good optical qualities that may be used as the receiving layer include, but are not limited to, Sylgard™ 184 Silicone Elastomer and OrmoStamp®. Sylgard™ 184 is manufactured by The Dow Chemical Company, City/State and OrmoStamp® is a registered trademark of Micro Resist Technology GmbH of Berlin, Germany. In other examples, the receiving layer may comprise another material including, but not limited to, other UV-curable polymers and even various thermoplastics materials such as poly (methyl methacrylate) (PMMA). According to various embodiments, the receiving layer (e.g., the UV-curable polymer) may be deposited as a layer on a surface of a substrate of the patterned device substrate. In some embodiments, the substrate may be a glass substrate.

In some embodiments (not illustrated), the method 100 of imprint lithography mold defect mitigation may further comprise forming a positive imprint lithography mold using the negative imprint lithography mold. In particular, the negative imprint lithography mold may be used to imprint a receiving layer of the positive imprint lithography mold, in some embodiments. In other embodiments, the negative imprint lithography mold may be employed directly without further imprinting a receiving layer to provide the positive imprint lithography mold. In some embodiments, the masking layer further defines one or both of a micrometer scale (microscale) and a nanometer scale (nanoscale) feature of the imprint lithography mold.

In some embodiments, the defect may be located between nanoscale features of the imprint lithography mold. In other embodiments, the defect may be a result of a so-called “stitch line” at a boundary between adjacent imprint lithography master substrates, in some embodiments. For example, the imprint lithography mold may be a plurality of imprint lithography master substrates that are tiled or arranged adjacent to one another. An interface or the stitch line at the boundary between the tiled imprint lithography master substrates may result in the defect, in some embodiments. In an optical device fabricated using the imprint lithography mold, the defect may result in unintended optical scattering, for example. Mitigation of the defect as described herein may reduce or eliminate the unintended optical scattering, according to various embodiments.

FIG. 2 illustrates a flow chart of a method 200 of surface defect mitigation in imprint lithography in an example, according to another embodiment of the principles described herein. As illustrated in FIG. 2, the method 200 of surface defect mitigation in imprint lithography comprises selectively covering 210 a surface defect on or in a surface of an imprint lithography mold using a patterned masking layer to provide a masked imprint lithography mold. The method 200 illustrated in FIG. 2 further comprises employing 220 imprint lithography using the masked imprint lithography mold to form a negative imprint lithography mold. According to various embodiments, the surface defect may be between spaced-apart nanoscale features of the imprint lithography mold. In addition, the surface defect may be mitigated by the selectively covered using the patterned masking layer.

In some embodiments (not illustrated), the method 200 of surface defect mitigation in imprint lithography further comprises employing imprint lithography using the negative imprint lithography mold to form a patterned device substrate. In other embodiments, the method 200 of surface defect mitigation in imprint lithography further comprises employing imprint lithography to form a positive imprint lithography mold using the negative imprint lithography mold. In these embodiments, employing imprint lithography to form a positive imprint lithography mold may further comprise using the positive imprint lithography mold to form a patterned device substrate using imprint lithography.

In some embodiments, the patterned masking layer comprises a patterned photoresist. In these embodiments, selectively covering a surface defect may comprise applying a photoresist to the surface of the imprint lithography mold having the surface defect. Selectively covering 210 the surface defect may further comprise patterning the photoresist using a photolithographic mask to expose the photoresist. Selectively covering 210 the surface defect may further comprise developing the exposed photoresist to provide the patterned masking layer on the surface of the imprint lithography mold to provide the masked imprint lithography mold.

In other embodiments of the method of surface defect mitigation in imprint lithography, the patterned masking layer may comprise a patterned preform film. In these embodiments, selectively covering 210 the surface defect comprising aligning the patterned masking layer with the imprint lithography mold having the surface defect. Selectively covering 210 the surface defect then further comprises applying the patterned preform film to the surface.

In some embodiments (e.g., as illustrated in FIG. 2), method 200 of surface defect mitigation in imprint lithography further comprises tiling 230 a pair of imprint lithography master substrates to form the imprint lithography mold. Tiling 230 the pair of imprint lithography master substrates may comprise abutting the imprint lithography master substrates to one another. The imprint lithography master substrates may be abutted on a carrier, for example. Tiling 230 the pair of imprint lithography substrate masters forms the imprint lithography mold from the tiled lithography master substrate pair. The surface defect may be created in the imprint lithography mold at a stitch boundary between the pair of imprint lithography master substrates, in these embodiments.

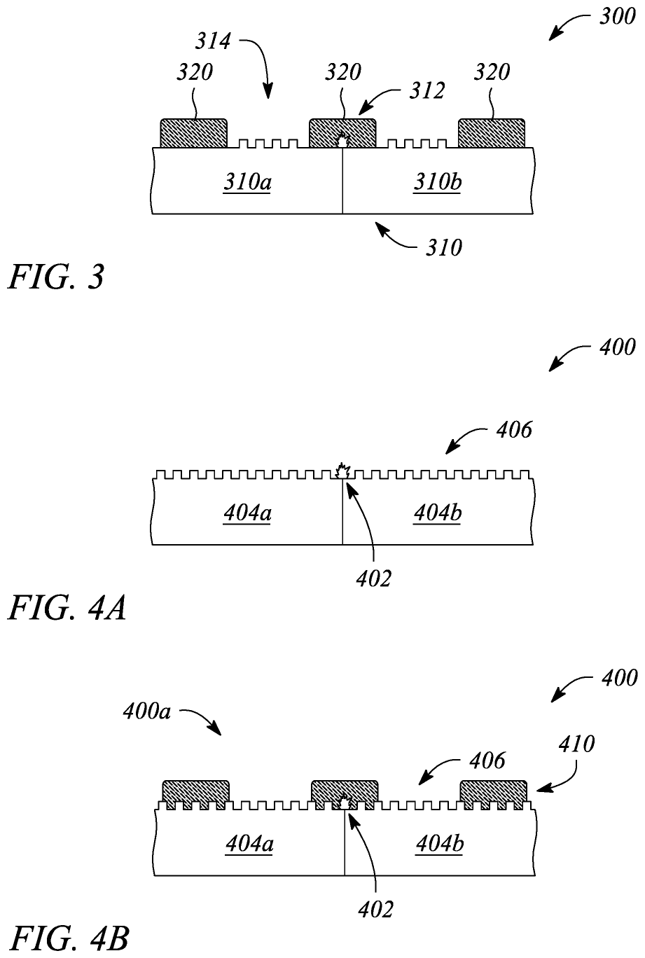

In other embodiments of the principles described herein, a masked imprint lithography mold is provided. FIG. 3 illustrates a cross-sectional view of a masked imprint lithography mold 300 in an example, according to an embodiment consistent with the principles described herein. As illustrated, the masked imprint lithography mold 300 comprises an imprint lithography mold 310 having a surface with a defect 312. FIG. 3 also illustrates nanoscale features 314 on the surface of the imprint lithography mold 310. In some embodiments, the imprint lithography mold 310 may comprise a pair of imprint lithography master substrates 310a, 310b. In these embodiments, the defect may correspond to a boundary or stitch line between the pair of imprint lithography master substrates 310a, 310b.

The masked imprint lithography mold 300 further comprises a patterned masking layer 320 affixed to the surface. In particular, the patterned masking layer 320 when affixed is configured to cover the defect 312. According to various embodiments, the defect 312 covered by the patterned masking layer 320 is configured to mitigate an effect of the defect 312 when the masked imprint lithography mold 300 is employed in imprint lithography.

According to some embodiments, the patterned masking layer 320 may comprise a patterned photoresist. For example, photoresist may be applied to a surface of the imprint lithography mold 310 and then exposed and developed to provide the patterned photoresist, e.g., as described above. In other embodiments, the patterned masking layer may comprise a patterned preform film provided on the surface of the imprint lithography mold 310.

### EXAMPLES

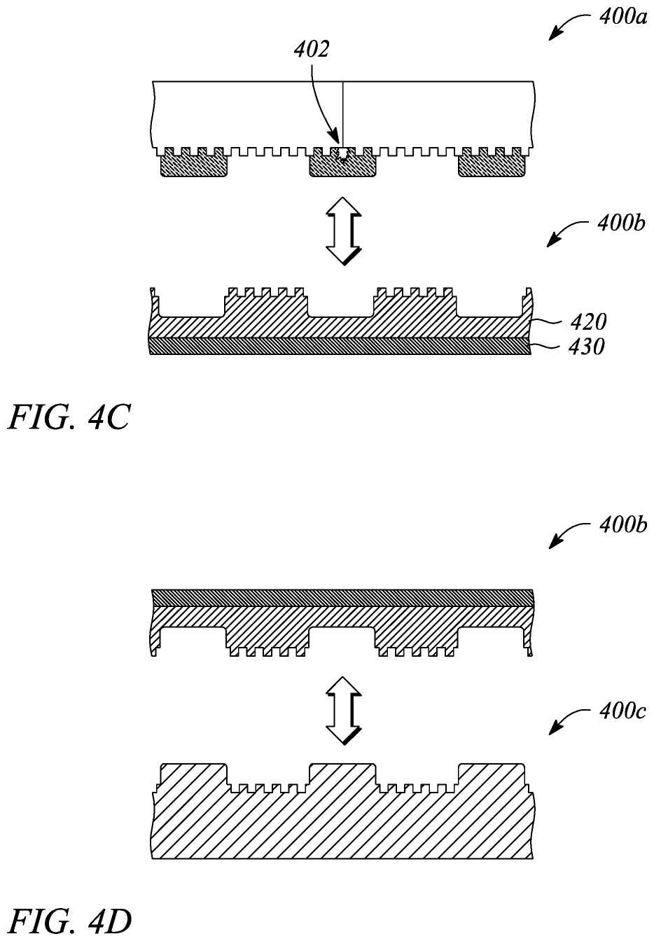

FIG. 4A illustrates a cross-sectional view of an imprint lithography mold 400 in an example, according to an embodiment consistent with the principles described herein. In particular, as illustrated the imprint lithography mold 400 has a defect 402 at a surface of the imprint lithography mold 400. For example, the defect 402 may be a result of a stitch line between a pair of tiled master substrates 404a, 404b, as illustrated. In other examples, the defect 402 may be located between nanoscale or microscale features or portions of a nanoscale surface pattern 406 on the imprint lithography mold 400. In yet other examples, the defect 402 result from various other causes including, but not limited to, process errors or material defects, scratching, impacts, developer spots, resist lifting or collapse, or contamination during fabrication of either the imprint lithography mold 400 or the constituent tiled master substrates 404a, 404b. The presence of the defect 402 may adversely affect operation or behavior of imprint lithography mold 400 during imprint lithography. Therefore, mitigation of the defect 402 may prove useful in many instances, especially where the imprint lithography mold 400 is to be used to produce optical devices that may be particularly sensitive to the presence of the defect 402. For example, the method 100 of imprint lithography mold defect mitigation may be applied to the imprint lithography mold 400 to minimize or even eliminate any effect that the defect 402 may have in using the imprint lithography mold 400.

FIG. 4B illustrates a cross-sectional view of the imprint lithography mold 400 of FIG. 4A in an example, according to an embodiment of the principles described herein. In particular, FIG. 4B illustrates the imprint lithography mold 400 following deposition of a masking layer 410 on a surface of an imprint lithography mold 400 to selectively cover the defect 402 on the imprint lithography mold surface. As illustrated, the masking layer 410 also covers portions of the nanoscale surface pattern 406, by way of example and not limitation. As such, the masking layer 410 may not only serve to selectively cover the defect 402 but may also contribute to definition of various nanoscale features within or across the nanoscale surface pattern 406 on the imprint lithography mold 400, in some embodiments.

According to some embodiments, the masking layer 410 may comprise a patterned, exposed, and developed photoresist layer as is described above and also described with respect to the method 100 of imprint lithography mold defect mitigation. In other embodiments, the masking layer may comprise a patterned preform film provided, aligned with, and applied to the surface of the imprint lithography mold 400 as mentioned above and also as described in the method 100 of imprint lithography mold defect mitigation. FIG. 4B also illustrates a masked imprint lithography mold 400a that results from the deposition of the masking layer 410 along with the constituent tiled master substrates 404a, 404b.

FIG. 4C illustrates a cross-sectional view of a negative imprint lithography mold 400b in an example, according to an embodiment consistent with the principles described herein. As illustrated, the negative imprint lithography mold 400b may be formed by imprint lithography using the masked imprint lithography mold 400a of FIG. 4B. In particular, negative imprint lithography mold 400b may be formed pressing the masked imprint lithography mold 400a into a receiving layer 420 on a substrate 430, as described above with respect to the method 100 of imprint lithography mold defect mitigation.

In FIG. 4C, the masked imprint lithography mold 400a along with a double-headed arrow are illustrated to depict the masked imprint lithography mold 400a being pressed into and removed from the receiving layer 420 of the negative imprint lithography mold 400b during imprint lithography. As illustrated, the negative imprint lithography mold 400b may be free or substantially free of the defect 402 that was originally present on the imprint lithography mold 400 of FIG. 4A prior to deposition of the masking layer 410 to form the masked imprint lithography mold 400a, as illustrated in FIG. 4B.

FIG. 4D illustrates a cross-sectional view of a positive imprint lithography mold 400c in an example, according to an embodiment consistent with the principles described herein. As illustrated the positive imprint lithography mold 400c may have a profile that is substantially similar to the masked imprint lithography mold 400a. The positive imprint lithography mold 400c may be formed according to imprint lithography using the negative imprint lithography mold 400b of FIG. 4C. For example, the negative imprint lithography mold 400b may be pressed into a surface of the positive imprint lithography mold 400c to imprint the surface (e.g., pressed into a receiving layer of the imprint lithography mold 400c), as in the above-described method 100 of imprint lithography mold defect mitigation. In FIG. 4D the negative imprint lithography mold 400b along with a double-headed arrow to depict the negative imprint lithography mold 400b being pressed into and removed from the surface of the positive imprint lithography mold 400c during imprint lithography.

In some embodiments, the positive imprint lithography mold 400c may comprise materials having consistent or desired optical qualities that may not be able to be realized in either or both of the masked imprint lithography mold 400a and the negative imprint lithography mold 400b. For example, both a substrate material and material of the receiving layer may be optical materials that are index matched to one another. As such, the positive imprint lithography mold 400c may serve as an optical device (e.g., a light guide with nanoscale surface scatterers) instead of as an imprint lithography mold, in some examples.

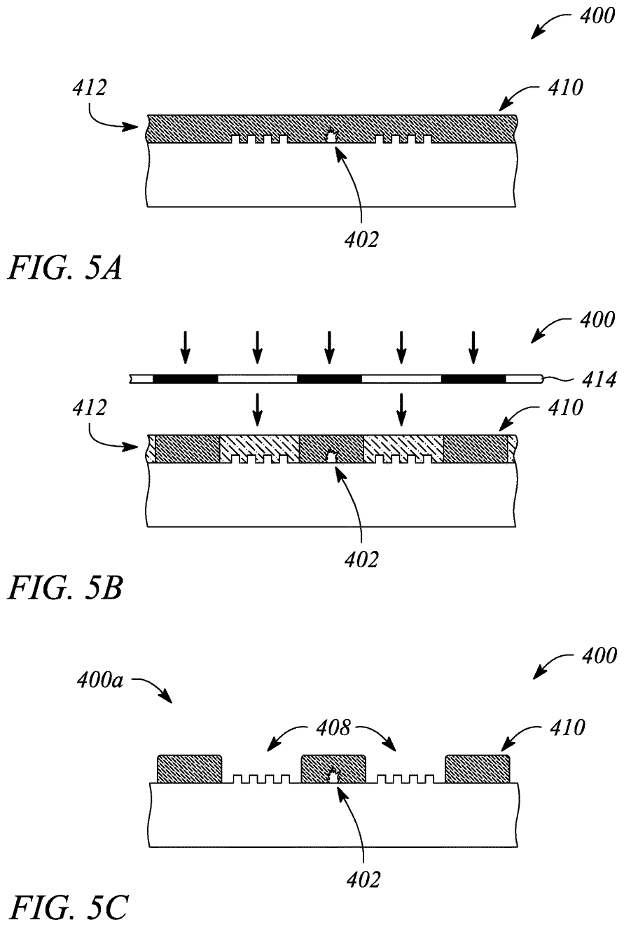

FIGS. 5A-5C illustrate a cross-sectional view of an imprint lithography mold 400 having a defect 402 in an example, according to an embodiment consistent with the principles described herein. FIGS. 5A-5C also illustrates depositing a masking layer 410 to provide a masked imprint lithography mold 400a. In some embodiments, depositing a masking layer 410 as illustrated in FIGS. 5A-5C may be substantially similar to depositing 110 a masking layer as described above with respect to the method 100 of imprint lithography mold defect mitigation.

In particular, a layer of photoresist 412 is illustrated in FIG. 5A after being applied to the surface of the imprint lithography mold 400. While illustrated in FIG. 5 as a positive photoresist, in general the photoresist 412 may be either a positive photoresist or a negative photoresist, according to various embodiments. FIGS. 5A and 5B also illustrate a photomask 414 used to pattern the photoresist 412.

In FIG. 5B ultraviolet (UV) light is illustrated passing through the photomask 414 to selectively expose the photoresist 412. Cross hatching is used to distinguish exposed portions of the photoresist 412 from portions that remain unexposed.

FIG. 5C illustrates the masked imprint lithography mold 400a following development of the exposed photoresist 412 on the imprint lithography mold 400 having the defect 402. The masked imprint lithography mold 400a includes a finished patterned masking layer 410 selectively covering the defect 402, as illustrated. FIG. 5C also illustrates the defect 402 being between spaced-apart nanoscale features 408 of the imprint lithography mold 400.

Thus, there have been described examples of imprint lithography mold defect mitigation that employs a masking layer to selectively cover a defect in or on a surface of an imprint lithography mold. It should be understood that the above-described examples are merely illustrative of some of the many specific examples that represent the principles described herein. Clearly, those skilled in the art can readily devise numerous other arrangements without departing from the scope as defined by the following claims.

1. A method of imprint lithography mold defect mitigation, the method comprising:
depositing a masking layer on a surface of an imprint lithography mold formed by a plurality of tiled imprint lithography master substrates to selectively cover a defect on the surface and form a masked imprint lithography mold; and
forming a negative imprint lithography mold from the masked imprint lithography mold, wherein the defect is a result of a stitch line at a boundary between the imprint lithography master substrates.

2. The method of imprint lithography mold defect mitigation of claim 1, wherein depositing the masking layer to selectively cover a defect comprises:
applying a photoresist to the surface of the imprint lithography mold having the defect;
patterning the photoresist using a photolithographic mask to expose the photoresist; and
developing the exposed photoresist to pattern the masking layer on the surface of the imprint lithography mold to form the masked imprint lithography mold.

3. The method of imprint lithography mold defect mitigation of claim 2, wherein applying the photoresist comprises coating the photoresist on the surface of the imprint lithography mold.

4. The method of imprint lithography mold defect mitigation of claim 1, wherein depositing the masking layer to selectively cover a defect comprises:
providing a patterned preform film;
aligning the patterned preform film with the imprint lithography mold having the defect; and
applying the patterned preform film to the surface of the imprint lithography mold to form the masking layer on the masked imprint lithography mold.

5. The method of imprint lithography mold defect mitigation of claim 1, wherein forming the negative imprint lithography mold comprises pressing the masked imprint lithography mold into a receiving layer on a substrate using imprint lithography, the substrate and receiving layer becoming the formed negative imprint lithography mold after pressing.

6. The method of imprint lithography mold defect mitigation of claim 1, further comprising forming a patterned device substrate using imprint lithography employing the negative imprint lithography mold to imprint a receiving layer of the patterned device substrate.

7. The method of imprint lithography mold defect mitigation of claim 6, wherein the receiving layer comprises ultraviolet-curable (UV-curable) hybrid polymer deposited as a layer on a surface of a glass substrate of the patterned device substrate.

8. The method of imprint lithography mold defect mitigation of claim 1, further comprising forming a positive imprint lithography mold using the negative imprint lithography mold to imprint a receiving layer of the positive imprint lithography mold.

9. The method of imprint lithography mold defect mitigation of claim 1, wherein the defect is between nanoscale features of the imprint lithography mold.

10. The method of imprint lithography mold defect mitigation of claim 1, wherein the masking layer further defines a nanoscale feature of the imprint lithography mold.

11. (canceled)

12. A method of surface defect mitigation in imprint lithography, the method comprising:
selectively covering a surface defect on a surface of an imprint lithography mold using a patterned masking layer to provide a masked imprint lithography mold; and
employing imprint lithography using the masked imprint lithography mold to form a negative imprint lithography mold,
wherein the surface defect is between spaced-apart nanoscale features of the imprint lithography mold, the surface defect being mitigated by selectively covering the surface defect using the patterned masking layer.

13. The method of surface defect mitigation in imprint lithography of claim 12, further comprising employing imprint lithography using the negative imprint lithography mold to form a patterned device substrate.

14. The method of surface defect mitigation in imprint lithography of claim 12, further comprising:
employing imprint lithography to form a positive imprint lithography mold using the negative imprint lithography mold; and
using the positive imprint lithography mold to form a patterned device substrate using imprint lithography.

15. The method of surface defect mitigation in imprint lithography of claim 12, wherein the patterned masking layer comprises a patterned photoresist, selectively covering the surface defect comprising:
applying a photoresist to the surface of the imprint lithography mold having the surface defect;
patterning the photoresist using a photolithographic mask to expose the photoresist; and
developing the exposed photoresist to provide the patterned masking layer on the surface of the imprint lithography mold to provide the masked imprint lithography mold.

16. The method of surface defect mitigation in imprint lithography of claim 12, wherein the patterned masking layer comprises a patterned preform film, selectively covering the surface defect comprising aligning the patterned masking layer with the imprint lithography mold having the surface defect and applying the patterned preform film to the surface.

17. The method of surface defect mitigation in imprint lithography of claim 12, further comprising:
tiling a pair of imprint lithography master substrates; and
forming an imprint lithography mold using the tiled lithography master substrate pair, the surface defect being created in the imprint lithography mold at a stitch boundary between the pair of imprint lithography master substrates.

18. A masked imprint lithography mold comprising:
an imprint lithography mold having a surface with a defect; and
a patterned masking layer affixed to the surface and configured to cover the defect,
wherein the patterned masking layer that selectively covers the defect is configured to mitigate an effect of the defect when the masked imprint lithography mold is employed in imprint lithography.

19. The masked imprint lithography mold of claim 18, wherein the patterned masking layer comprises one of a patterned photoresist and a patterned preform film provided on the surface of the imprint lithography mold.

20. The masked imprint lithography mold of claim 18, wherein the imprint lithography mold comprises a pair of imprint lithography master substrates, and wherein the defect corresponds to a boundary between the pair of imprint lithography master substrates.
